(19) United States
(12) Patent Application Publication
(10) Pub. No.: US 2016/0126483 A1
(43) Pub. Date: May 5, 2016

(54) ZSO-BASED PEROVSKITE SOLAR CELL AND ITS PREPARATION METHOD

(71) Applicant: KOREA INSTITUTE OF SCIENCE AND TECHNOLOGY, Seoul (KR)

(72) Inventors: Jin Young KIM, Seoul (KR); Doh-Kwon LEE, Seoul (KR); Hong Gon KIM, Seoul (KR); Bong Soo KIM, Seoul (KR); Lee Seul OH, Seoul (KR); Min Ah PARK, Seoul (KR); Hae Jung SON, Seoul (KR); Min Jae KO, Seoul (KR)

(21) Appl. No.: 14/720,416

(22) Filed: May 22, 2015

(30) Foreign Application Priority Data
Nov. 5, 2014 (KR) 10-2014-0152799

(51) Int. Cl. H01L 51/42; H01L 51/00

(52) U.S. Cl. CPC H01L 51/4213; H01L 51/0084

(57) ABSTRACT

Provided is a new ternary Zn₂SnO₄ (ZSO) electron-transporting electrode of a CH₃NH₃PbI₃ perovskite solar cell as an alternative to the conventional TiO₂ electrode. The ZSO-based perovskite solar cell exhibits faster electron transport (˜10 times) and superior charge-collecting capability compared to the TiO₂-based perovskite solar cell with similar thickness and energy conversion efficiency.

### CROSS-REFERENCE TO RELATED APPLICATIONS

This application claims priority under 35 U.S.C. §119 to Korean Patent Application No. 10-2014-0152799 filed on Nov. 5, 2014, in the Korean Intellectual Property Office, the disclosure of which is incorporated herein by reference in its entirety.

### TECHNICAL FIELD

The present disclosure relates to a ZSO-based perovskite solar cell and a method for preparing the same.

### BACKGROUND

Organolead halide-based hybrid solar cells (or perovskite solar cells) are being spotlighted a lot in recent years as a new highly efficient solid-state thin film solar cell. The structure of the first perovskite solar cell stems from the dye-sensitized solar cell (DSSC), where the ruthenium-based or organic dye sensitizers have been replaced with organolead halide perovskites such as CH₃NH₃PbI₃ (methylammonium lead iodide; MALI). Afterward, some structural variations such as the mesoscopic heterojunction structure, planar heterojunction structure, incorporation of p-/n-type organic semiconductors, and so forth have been reported.

Most of the solar cells with planar structures are fabricated through either a solution process or thermal evaporation. In spite of these structural variations, the sensitized solar cell that incorporates a mesoscopic TiO₂ electron-transporting layer is still widely investigated.

Although development of a photoanode which exhibits faster charge injection from the sensitizer and electron diffusion through the nanoparticle layer than the TiO₂ photoanode while allowing for easy control of optoelectronic properties through composition change and impurity addition is required, no effective research result has been reported yet.

### REFERENCES OF THE RELATED ART

### Patent Documents

Korean Patent Registration No. 10-1337914.
Korean Patent Registration No. 10-1141868.

### Non-Patent Document

Applied Physics Letters 86, 053114 (2005).

### SUMMARY

The present disclosure is directed to providing a photoanode which exhibits faster charge injection from a sensitizer and electron diffusion through a nanoparticle layer than a TiO₂ photoanode while allowing for easy control of optoelectronic properties through composition change.

In an aspect, the present disclosure provides a solar cell including: (a) a transparent substrate; (b) a first Zn₂SnO₄ layer formed on the transparent substrate; (c) a second Zn₂SnO₄ layer formed on the first Zn₂SnO₄ layer; (d) a CH₃NH₃PbI₃ layer formed on the second Zn₂SnO₄ layer; and (e) a hole-transporting material layer formed on the CH₃NH₃PbI₃ layer.

In another aspect, the present disclosure provides a method for preparing a solar cell, including: (A) forming a first Zn₂SnO₄ layer on a transparent substrate; (B) forming a second Zn₂SnO₄ layer on the first Zn₂SnO₄ layer; (C) forming a CH₃NH₃PbI₃ layer on the second Zn₂SnO₄ layer; and (D) forming a hole-transporting material layer on the CH₃NH₃PbI₃ layer.

In accordance with the present disclosure, a photoanode which exhibits faster charge injection from a sensitizer and electron diffusion through a nanoparticle layer than a TiO₂ photoanode while allowing for easy control of optoelectronic properties through composition change and impurity addition can be prepared.

### BRIEF DESCRIPTION OF DRAWINGS

FIG. 1A shows X-ray diffraction patterns of samples at various preparation steps and FIG. 1B shows a cross-sectional SEM image of a ZSO-based perovskite solar cell.

FIG. 2 shows V_{OC} decay curves of ZSO-based perovskite solar cells with different c-ZSO thicknesses. The insert shows the response time (or electron lifetime) of the solar cells.

FIG. 3A to FIG. 3E show cross-sectional SEM images of mesoscopic ZSO layers spin-coated on an ITO substrate at different speeds and FIG. 3F shows the dependence of ZSO thickness on the rotation speed.

FIG. 4A shows a J-V curve and FIG. 4B shows electron diffusion coefficients of a ZSO-based perovskite solar cell (thickness=300 nm) with the highest conversion efficiency. The electron diffusion coefficients of a TiO₂-based solar cell with similar thickness (˜300 nm) and efficiency (˜7%) are also presented for comparison.

FIG. 5 shows J-V curves of perovskite solar cells having different compact layers.

FIG. 6 shows specular transmittance (left) and total transmittance (right) including scattered light of c-ZSO/FTO substrates with different c-ZSO thicknesses.

FIG. 7 shows transient photoresponse of TiO₂-based (left) and ZSO-based (right) perovskite solar cells with different chopping speeds.

### DETAILED DESCRIPTION OF EMBODIMENTS

Hereinafter, various aspects and exemplary embodiments of the present disclosure will be described in more detail.

In an aspect, the present disclosure provides a solar cell including: (a) a transparent substrate; (b) a first Zn₂SnO₄ layer formed on the transparent substrate; (c) a second Zn₂SnO₄ layer formed on the first Zn₂SnO₄ layer; (d) a CH₃NH₃PbI₃ layer formed on the second Zn₂SnO₄ layer; and (e) a hole-transporting material layer formed on the CH₃NH₃PbI₃ layer.

That is to say, according to an aspect of the present disclosure, the conventional TiO₂ layer is replaced by a compact first Zn₂SnO₄ layer and a porous second Zn₂SnO₄ layer which are adjacent to each other. The first Zn₂SnO₄ layer formed instead of the TiO₂ layer may prevent charge recombination from an FTO substrate and minimize loss of incident sunlight. And, due to the second Zn₂SnO₄ layer formed instead of the TiO₂ layer, a photoanode which exhibits faster charge injection from a sensitizer and electron diffusion through a nanoparticle layer may be obtained and photogenerated charges may be collected faster because of faster photoresponse saturation.

In addition, it is advantageous in that optoelectronic properties can be controlled easily through composition change and impurity addition.

In an exemplary embodiment, the first Zn₂SnO₄ layer has a compact (dense) structure. Specifically, it has a compact structure with a porosity of 0-5%, specifically 0-3%, more specifically 0-1%. The second Zn₂SnO₄ layer has a porous structure. Specifically, it has a porosity of 50-70% and an average pore size of 10-100 nm.

It was confirmed that, when the first Zn₂SO₄ layer has a porosity within the above range, the components on top of the FTO substrate may be physically separated, recombination resulting from reverse transportation of electrons from the FTO substrate toward the cell may be prevented, and loss of incident light may be reduced significantly.

It was also confirmed that, when the second Zn₂SO₄ layer has a porosity and an average pore size within the above ranges, photoelectrons generated from CH₃NH₃PbI₃ are injected to the first Zn₂SO₄ layer nanoparticle photoelectrode and current-collecting efficiency is significantly improved because conductivity is 10 times or more greater than the existing TiO₂ nanoparticle layer.

In another exemplary embodiment, the first Zn₂SnO₄ layer may have a thickness of 100-120 nm. It was confirmed that the remarkable effect of charge recombination prevention and electron lifetime increase is achieved only when the thickness of the compact ZSO layer is in the range of 100-120 nm and such a remarkable effect is not achieved when the thickness of the first Zn₂SnO₄ layer is outside the range.

In another exemplary embodiment, the second Zn₂SnO₄ layer may have a thickness of 250-350 nm. It was confirmed that the fill factor and open-circuit voltage decrease greatly when the thickness of the second Zn₂SnO₄ layer is smaller than 250 nm and that the short-circuit current decreases greatly when the thickness of the second Zn₂SnO₄ layer exceeds 350 nm.

In another exemplary embodiment, the transparent substrate may be selected from fluorine tin oxide (FTO), indium tin oxide (ITO), aluminum zinc oxide (AZO), niobium tin oxide (NTO) and zinc tin oxide (ZTO).

In another aspect, the present disclosure provides a method for preparing a solar cell, including: (A) forming a first Zn₂SnO₄ layer on a transparent substrate; (B) forming a second Zn₂SnO₄ layer on the first Zn₂SnO₄ layer; (C) forming a CH₃NH₃PbI₃ layer on the second Zn₂SnO₄ layer; and (D) forming a hole-transporting material layer on the CH₃NH₃PbI₃ layer.

In an exemplary embodiment, the step (A) may be performed by conducting first coating of a solution of ZnCl₂ and SnCl₂ on the transparent substrate and then conducting first annealing, thereby forming the first Zn₂SnO₄ layer. In particular, when the above materials are used as Zn and Sn precursors, a thin and uniform layer may be formed.

In another exemplary embodiment, a molar ratio of the Zn precursor and the Sn precursor in the solution may be 1.9-2.1. When the molar ratio of the Zn precursor and the Sn precursor in the solution is smaller than the lowest limit or exceeds the highest limit, a secondary phase may be formed in addition to the Zn₂SnO₄ layer.

In another exemplary embodiment, the first coating may be spin coating and the first annealing may be conducted at 300-400° C. for 5-20 minutes. When the temperature of the first annealing is below the lowest limit, anions may remain in the layer. And, when it exceeds the highest limit, surface roughness of the layer may increase or deterioration of the FTO substrate may occur due to increased crystal size. And, when the first annealing time is shorter than the lowest limit or exceeds the highest limit, anions may remain in the layer.

In another exemplary embodiment, the first coating may be conducted by performing spin coating at 2000-4000 rpm for from 20 seconds to 1 minute. When the first coating time is shorter than the lowest limit, it may be difficult to form a uniform layer. And, it may be difficult to form a uniform layer and the layer may become excessively thick when the rotation speed of the first coating is below the lowest limit, and the layer may become excessively thin or the FTO substrate below may be exposed when the rotation speed exceeds the highest limit.

In another exemplary embodiment, the step (B) may be performed by conducting second coating of a Zn₂SnO₄ nanoparticle on the first Zn₂SnO₄ layer and then conducting second annealing.

In another exemplary embodiment, the second coating may be conducted by performing spin-coating a Zn₂SnO₄ nanoparticle paste diluate. When the paste is not diluted, it is impossible to form a thin layer with a uniform thickness of hundreds of nanometers due to high viscosity. In addition, when doctor blade coating or screen printing is used instead of the spin coating, it is impossible to form a thin layer with a thickness of hundreds of nanometers.

In another exemplary embodiment, the diluate may be obtained by diluting a Zn₂SnO₄ nanoparticle paste with a terpineol solvent. In the present disclosure, an alcohol-based solvent such as terpineol, ethanol, isopropanol, etc. or a mixture solvent thereof may be used to prepare the diluate. Particularly, when terpineol is used as a solvent in particular, it is advantageous in that the functions of the additives added together may be maintained because terpineol is a constituent of the paste. However, when other solvents are used, there may occur a problem that the additives are dissolved.

In another exemplary embodiment, the second annealing may be conducted at 450-550° C. for from 15 minutes to 1 hour. When the temperature of the second annealing is below the lowest limit, organic materials included in the coating solution may remain in the layer. And, when it exceeds the highest limit, disruption of the pore structure or deterioration of the FTO substrate may occur due to increased nanoparticle size. When the second annealing time is shorter than the lowest limit, organic materials included in the coating solution may remain in the layer. And, when the time exceeds the highest limit, disruption of the pore structure or deterioration of the FTO substrate may occur due to increased nanoparticle size.

In another exemplary embodiment, the step (C) may be performed by (C′) coating a PbI₂ solution on the second Zn₂SnO₄ layer and conducting third annealing and then (C″) immersing in a CH₃NH₃I solution and conducting fourth annealing.

In another exemplary embodiment, the coating of the PbI₂ solution in the step (C′) may be performed by applying the PbI₂ solution and then conducting spin coating after waiting for from 10 seconds to 1 minute, and the immersion in the CH₃NH₃I solution in the step (C″) may be performed by immersing in the CH₃NH₃I solution and then waiting for from 20 seconds to 1 minute. When the above-described time passes after the PbI₂ solution has been applied, the remaining of pores after the layer has been formed may be prevented as the mesopores of the second Zn₂SnO₄ layer are filled. And, when the above-described time passes after the immersion in the CH₃NH₃I solution, a uniform CH₃NH₃PbI₃ layer may be formed. When the time is shorter than the lowest limit, unreacted PbI₂ may remain. And, when it exceeds the highest limit, the formed CH₃NH₃PbI₃ may be dissolved again in the solvent.

In another exemplary embodiment, the spin coating may be conducted at 6000-7000 rpm for 20-40 seconds. When the rotation speed of the spin coating is below the lowest limit, PbI₂ may remain even after the immersion in the CH₃NH₃I solution because the PbI₂ layer becomes excessively thick. And, when it exceeds the highest limit, the mesopores of the oxide layer may not be formed completely or the upper layer may not be formed adequately. When the spin coating time is shorter than the lowest limit, a nonuniform PbI₂ layer may be formed.

In another exemplary embodiment, the third annealing may be conducted at 70-90° C. for 15-30 minutes, and the fourth annealing may be conducted at 70-90° C. for 15-30 minutes. When the third annealing temperature is below the lowest limit, crystallization of PbI₂ may be insufficient. And, when it exceeds the highest limit, PbI₂ may remain even after the immersion in the CH₃NH₃I solution due to excessive crystallization of PbI₂. When the fourth annealing temperature is below the lowest limit, crystallization of CH₃NH₃PbI₃ may be insufficient. And, when it exceeds the highest limit, phase separation of CH₃NH₃PbI₃ may occur.

In another exemplary embodiment, the PbI₂ solution may be a solution wherein PbI₂ is dissolved in DMF, and the CH₃NH₃I solution may be a solution wherein CH₃NH₃I is dissolved in isopropanol. To prepare the PbI₂ solution, dimethylformamide (DMF), γ-butyrolactone (GBL), dimethyl sulfoxide (DMSO) and a mixture solvent thereof may be used. In particular, when DMF is used as a solvent, it is easy to form a uniform layer. And, in order to prepare the CH₃NH₃I solution, an alcohol-based solvent such as isopropanol, ethanol, etc. or a mixture solvent thereof may be used. In particular, when isopropanol is used as a solvent, it is advantageous in that a uniform reaction can be achieved and redissolution after the CH₃NH₃PbI₃ layer has been formed is relatively slow.

In another exemplary embodiment, the step (D) may be performed by spin-coating a spiro-OMeTAD solution on the CH₃NH₃PbI₃ layer.

The spin coating may be performed at 3000-5000 rpm for 20-40 seconds.

### EXAMPLES

Hereinafter, the present disclosure will be described in more detail through examples. However, the scope and content of the present disclosure should not be interpreted as being reduced or limited by the examples. It will be obvious that those of ordinary skill can easily carry out the present disclosure based on the disclosure of the present disclosure including the examples even when specific experimental results are not provided and that such changes and modifications are included in the scope of the appended claims.

Materials

2,2′,7,7′-Tetrakis(N,N′-di-p-methoxyphenylamine)-9,9′-spirobifluorene (spiro-OMeTAD) was purchased from Merck and CH₃NH₃I was synthesized from methylamine and hydroiodic acid according to the literature. All other chemicals were purchased from Sigma Aldrich and used as received unless stated otherwise.

### Example

### Preparation of ZSO-Based Solar Cell

F-doped SnO₂ (FTO) substrates (TEC8, Pilkington) were patterned using a laser scriber (ML20-PL-R, Kortherm Science) and cleaned by sonication in ethanol and isopropanol, followed by UV-ozone treatment before coating a compact layer.

For preparation of a ZSO-based solar cell, a compact ZSO layer was formed on the patterned FTO substrate by spin-coating a solution of ZnCl₂ and SnCl₂ (Zn/Sn ratio=2) at room temperature at 3000 rpm for 30 seconds, followed by annealing at 350° C. for 10 minutes.

Then, a synthesized ZSO nanoparticle paste was diluted with terpineol and spin-coated on thereon, followed by annealing at 500° C. for 30 minutes. The thickness of the mesoscopic ZSO layer could be controlled by changing the speed of spin coating.

A PbI₂ solution (462 mg/cc in N,N-dimethylformamide; DMF) was spread on the ms-ZSO layer, infiltrated to the mesopores for 20 seconds and then spin-coated at 6500 rpm for 30 seconds, followed by annealing at 80° C. on a hot plate. Then, the formed PbI₂/ms-oxide layer was immersed in a CH₃NH₃I solution (10 mg/cc in isopropanol) for 30 seconds to form a MALI/ms-oxide layer, followed by annealing at 80° C. on a hot plate.

Then, a spiro-OMeTAD solution prepared according to the literature with slight modification (i.e., exclusion of the Co complex) was spin-coated thereon at 4000 rpm for 30 seconds to form a hole-transporting material (HTM) layer with a thickness of about 110 nm.

### Comparative Example

### Preparation of TiO₂-Based Solar Cell

For preparation of a TiO₂-based perovskite solar cell, a compact TiO₂ (c-TiO₂) layer was formed by spin-coating a titanium diisopropoxide bis(acetylacetonate) solution (75 wt % in isopropanol) mixed with n-butanol (1:11 in volume ratio) on the patterned FTO substrate at 500 rpm for 5 seconds, at 1000 rpm for 5 seconds and at 2000 rpm for 40 seconds, in sequence, followed by annealing at 470° C. for 30 minutes.

Then, a commercially available TiO₂ paste (Dyesol 18NRT, Dyesol) was diluted with ethanol (2:7 weight ratio) and spin-coated, followed by annealing at 500° C. for 30 minutes. The thickness of the mesoscopic TiO₂ layer (ms-TiO₂) could be controlled to 300 nm by adjusting the spin coating conditions. The whole processes after the formation of the mesoscopic oxide layer were performed in a fumed hood under an ambient atmosphere.

A PbI₂ solution (462 mg/cc in N,N-dimethylformamide; DMF) was spread on the ms-TiO₂ layer, infiltrated to the mesopores for 20 seconds and then spin-coated at 6500 rpm for 30 seconds, followed by annealing at 80° C. on a hot plate. Then, the formed PbI₂/ms-oxide layer was immersed in a CH₃NH₃I solution (10 mg/cc in isopropanol) for 30 seconds to form a MALI/ms-oxide layer, followed by annealing at 80° C. on a hot plate.

Then, a spiro-OMeTAD solution prepared according to the literature with slight modification (i.e., exclusion of the Co complex) was spin-coated thereon at 4000 rpm for 30 seconds to form a hole-transporting material (HTM) layer with a thickness of about 110 nm.

### Test Example and Comparative Test Example

The samples prepared in Example and Comparative Example were transferred to a thermal evaporation chamber (SJH-2A, Ultech) and a gold electrode with a thickness of about 100 nm was deposited using a mask for electrode patterning. The active area of each solar cell was measured to be generally 0.15-0.2 cm² using an optical microscope.

The microstructure and crystallographic structure of the samples prepared in Example and Comparative Example were analyzed by filed-emission scanning electron microscopy (FE-SEM; S-4200, Hitachi) and X-ray diffraction (XRD; D-max 2500/server, Rigaku). Optical properties were characterized by UV-Vis spectroscopy (Lambda 35, Perkin Elmer). Spectral photoresponses were measured using an incident photon-to-current conversion efficiency measurement system (PV Measurements) and the current density-voltage curves of the solar cells with the portion other than the active area masked could be obtained using a solar simulator (Peccell Technology, 100 mW/cm², AM 1.5) and a potentiostat (CHI 608C, CH Instruments). The light intensity of the solar simulator was calibrated using a reference cell (PV Measurements). Time constants for electron transport were measured with a weak laser pulse at 532 nm superimposed on a relatively large bias illumination at 680 nm using a transient photocurrent-voltage measurement setup. The transient photocurrent response was recorded at different frequencies under a 550 nm monochromatic beam.

Structural Observation with Preparation Steps

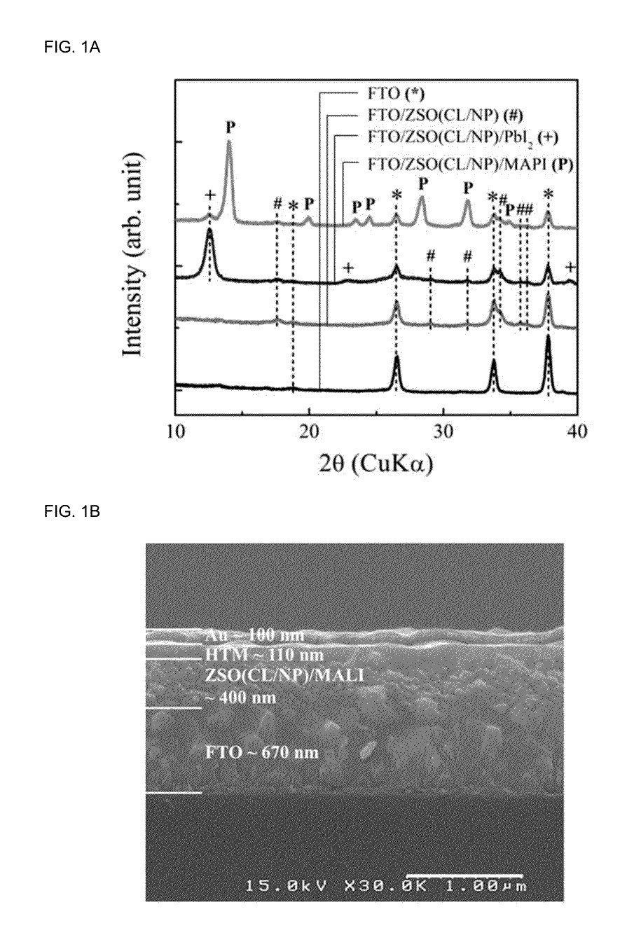

The perovskite solar cells were fabricated via the two-step process as described above. Specifically, the ZSO or TiO₂ compact layer was deposited on the patterned FTO substrate by spin coating and then the diluted ZSO or TiO₂ nanoparticle paste was spin-coated to form the mesoscopic ZSO or TiO₂ layer. After annealing the compact/mesoscopic oxide layers, the PbI₂/oxide layer was prepared by spin-coating the solution of PbI₂ in DMF, followed by immersing in the methylammonium iodide solution to form the methylammonium lead iodide/oxide film. Then, the hole-transporting layer (spiro-OMeTAD) and a current-collecting layer (Au) were deposited by spin coating and thermal evaporation, respectively. Crystallographic structures and cross-sectional SEM images at various preparation steps are shown in FIG. 1B.

FIG. 1A shows the evolution of the crystallographic structure during the fabrication process of the ZSO-based perovskite solar cell. The diffraction peaks from the FTO substrate (JCPDS no. 46-1088), the ZSO compact/mesoscopic layers (JCPDS no. 74-2184), PbI₂ (JCPDS no.07-0235) and MALI are denoted by ‘*’, ‘#’, ‘+’ and ‘P’, respectively. Most of the peaks in the X-ray diffraction pattern of the MALI/ZSO film can be assigned to those from MALI, ZSO or FTO except for the small peak at 12.56° which is from the unreacted (or decomposed) PbI₂.

FIG. 1B shows a cross-sectional SEM image. Stacked layers of the ZSO-based perovskite solar cell consisting of the FTO substrate (˜670 nm), the ZSO compact layer (˜100 nm), the mesoscopic ZSO particle film filled with MALI (˜300 nm), the hole-transporting material (HTM; spiro-OMeTAD, ˜110 nm), and Au (˜100 nm) can be clearly observed in the image.

It was also found out through experiments that the presence of the compact ZSO layer as opposed to the compact TiO₂ layer is crucial for having the ZSO-based perovskite solar cell work properly.

Blocking Effect Depending on Thickness of ZSO Compact Layer

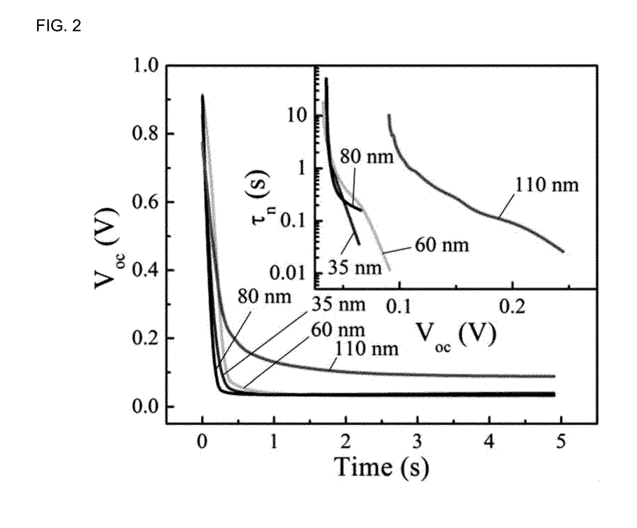

FIG. 2 shows the blocking layer effect of the compact ZSO layers with different thicknesses. The open-circuit voltage decayed faster than dye-sensitized solar cells regardless of the compact layer thickness, and the compact ZSO layer having a thickness of 110 nm showed a significantly retarded back-electron transfer compared to the thinner ZSO layers

In addition to the significantly retarded back-electron transfer, a significantly increased electron lifetime was observed only when the thickness of the compact ZSO layer was in the range from 100 nm to 120 nm, although the data were not presented.

Control of Thickness of ZSO Mesoscopic Layer

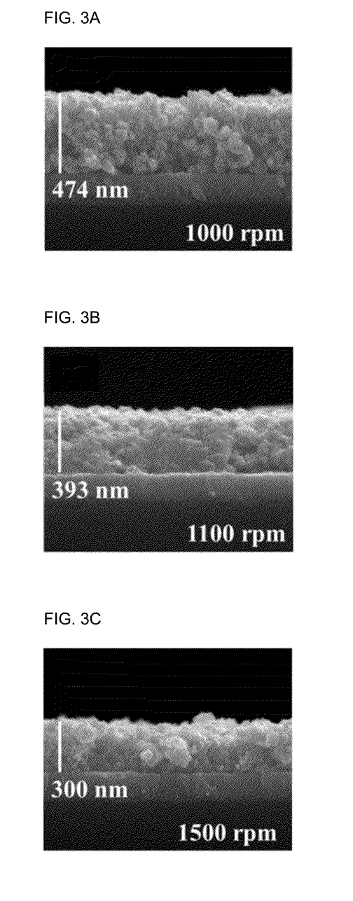

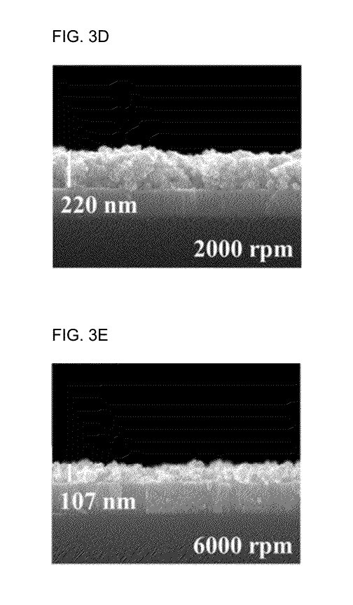

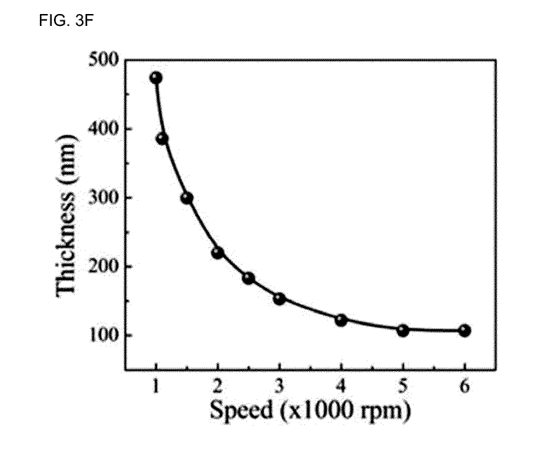

FIGS. 3A to 3F show the effect of the spin-coating speed on the thickness of the mesoscopic ZSO layer. For a clear comparison, ITO substrates with much smoother surface were used instead of the FTO substrates. The thickness of the mesoscopic ZSO layer could be controlled variously from 100 nm to 500 nm by changing the spin-coating speed from 6000 rpm to 1000 rpm.

Effect of Thickness of ZSO Mesoscopic Layer

Based on the result of investigating the electron-blocking effect with various compact ZSO layer thicknesses, the effect of the mesoscopic ZSO layer thickness was investigated with the compact ZSO layer fixed at 110 nm. As a result, it was found out that the fill factor and the open-circuit voltage decrease greatly when the thickness is smaller than 250 nm and that the short-circuit current decreases greatly when the thickness exceeds 350 nm.

Current Density-Voltage Curve of ZSO Substrate Perovskite Solar Cell

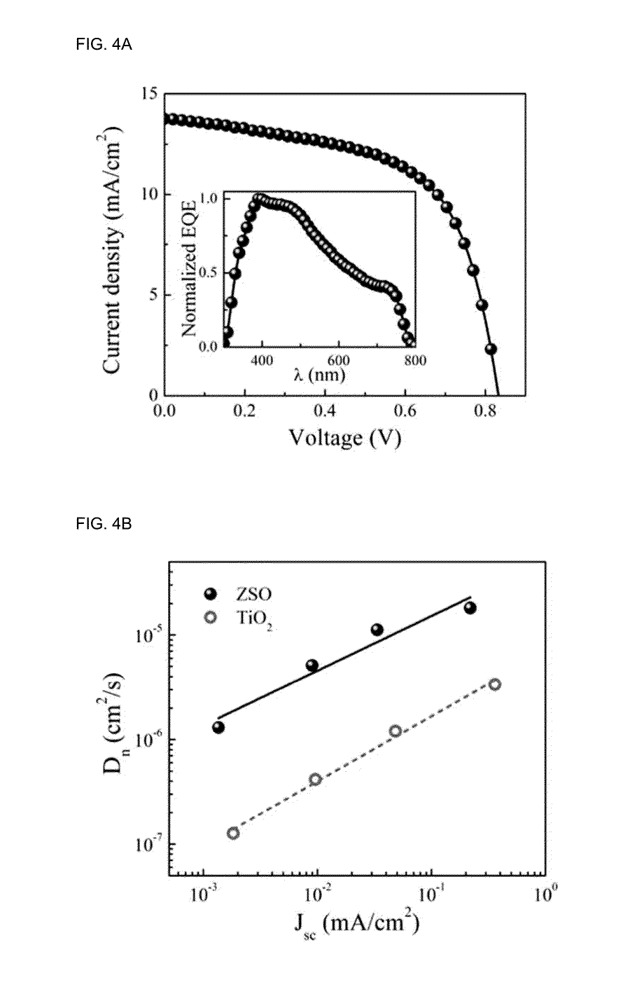

FIG. 4A shows the current density-voltage curve of the ZSO-based perovskite solar cell with a 300-nm thick mesoscopic ZSO layer that showed the highest conversion efficiency. The insert shows the normalized external quantum efficiency (EQE).

The short-circuit current, the open-circuit voltage, the fill factor and the conversion efficiency were 13.78 mA/cm², 0.83V, 61.4% and 7.02%, respectively. When compared with the TiO₂-based solar cell with similar geometry and synthetic procedure (J_{SC}≈20 mA/cm², V_{OC}≈1 V, FF≈70%, η≈14%), the short-circuit current, the open-circuit voltage and the fill factor are smaller by 31%, 17% and 12%, respectively, resulting in 50% decrease in the conversion efficiency.

The smaller short-circuit current can be explained by the spectral photoresponse as shown in the EQE curve in FIG. 4A. The photoresponse or quantum efficiency in the longer wavelength region (λ>500 nm) is significantly lower compared to that in the shorter wavelength region. In general, the poor photoresponse in the shorter wavelength region or near the band edge can be ascribed to poor charge collection and increased recombination of the photoelectrons and holes generated near the back contact owing to the weaker absorption of the low-energy photons by the absorber material. The poor photoresponse can also be ascribed to the small amount of the absorber material or the insufficient formation of the MALI overlayer on top of the mesoscopic ZSO layer because of the same wavelength-dependent absorption issue. The smaller open-circuit voltage can result from the conduction band edge position of ZSO, which is lower by about 200 mV compared to TiO₂. However, based on experience, the effect on the conduction band position on the open-circuit voltage becomes weaker when the electron-transporting phase (ZSO) is physically separated from the hole-transporting material (spiro-OMeTAD) as a complete MALI layer is formed between them. Therefore, the formation of the uniform MALI layer on top of the mesoscopic ZSO layer via an optimized process can lead to increased short-circuit current and open-circuit voltage.

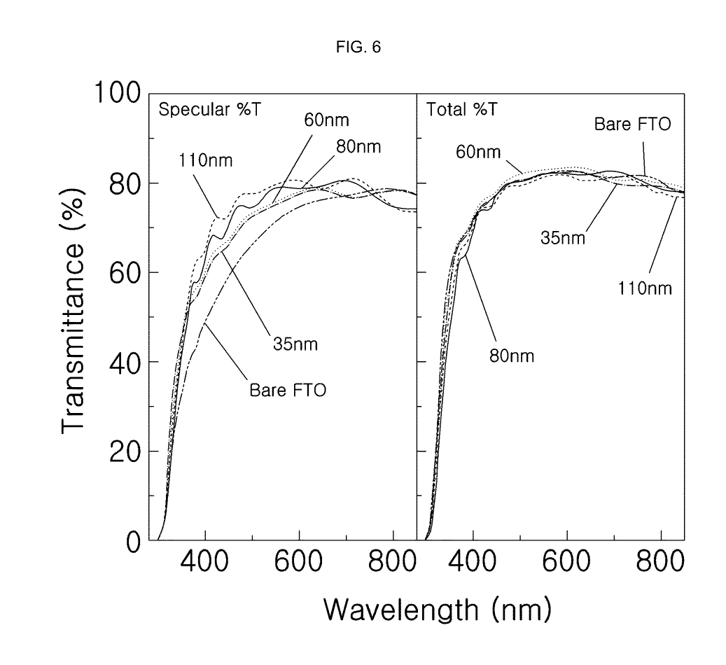

FIG. 4B shows the electron diffusion coefficients of the ZSO-based perovskite solar cell that showed the highest efficiency under various short-circuit currents. The electron diffusion coefficients of the TiO₂-based solar cell with similar thickness and efficiency are displayed together for comparison. The solid and dotted lines represent best fit of the data. Both exhibit exponential increase of the electron diffusion coefficient on the short-circuit current (photoelectron density) as observed for other perovskite solar cells and dye-sensitized solar cells. In the whole range of the short-circuit current, the ZSO-based perovskite solar cell exhibits about 10-times larger electron diffusion coefficient than the TiO₂-based perovskite solar cell. This result is very consistent with the previous study on the ZSO-based dye-sensitized solar cell using the iodide electrolyte, where the ZSO showed about 10-times larger electron diffusion coefficient than TiO₂. The frequency-dependent time-resolved photoresponse measurement (FIG. 6) also revealed that the ZSO-based perovskite solar cell shows superior charge-collecting capability compared to the TiO₂-based counterpart, which is in consistent with its larger diffusion coefficient. The faster electron diffusion in the mesoscopic oxide layer can be particularly beneficial for the perovskite solar cells in terms of the balanced electron/hole mobility, given the geometric similarity to the heterojunction solar cells.

Comparison of J-V Curves of Perovskite Solar Cells Having TiO₂ and ZSO Compact Layers

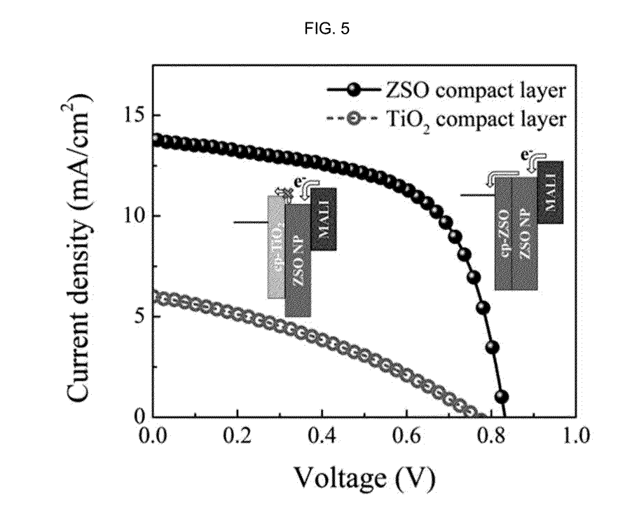

FIG. 5 shows the effect of the different compact layers on the performance of the ZSO-based perovskite solar cells. It was confirmed that, whereas the solar cell with the compact ZSO layer works well, the one with the compact TiO₂ layer does not function properly because the high conduction band of TiO₂ blocks the flow of photoelectrons from ZSO nanoparticles to the FTO substrate.

Comparison of Transmittance of Perovskite Solar Cells with Different ZSO Compact Layer Thicknesses

FIG. 6 shows a result of measuring the specular transmittance and total transmittance of c-ZSO/FTO substrates with different c-ZSO thicknesses. It can be seen that the specular transmittance increases with the increasing c-ZSO thickness, whereas the total transmittance is not influenced by the thickness.

Comparison of Photoresponse of Perovskite Solar Cells Having TiO₂ and ZSO Compact Layers

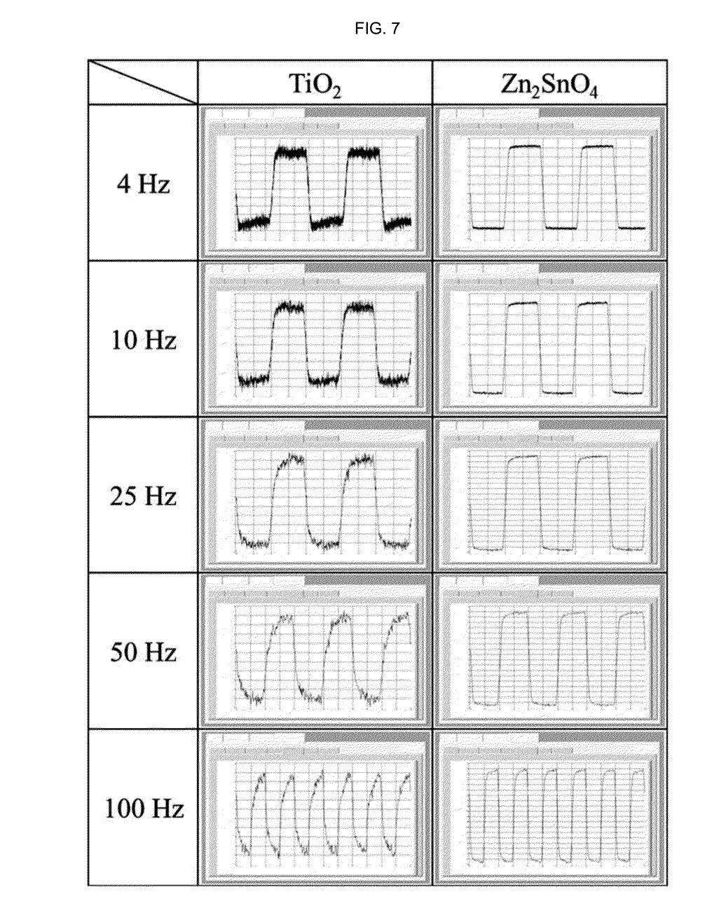

FIG. 7 shows the frequency dependence of the time-resolved photoresponse measurements for the ZSO- and TiO₂-based perovskite solar cells with similar thickness (300 nm) and efficiency, where one can compare the charge-collecting capabilities. It can be seen that at a given frequency the photoresponse of the ZSO-based perovskite solar cell gets saturated much faster than the TiO₂-based perovskite solar cell, suggesting that the photogenerated charges are collected much faster for the ZSO-based perovskite solar cell.

As described above, the open-circuit voltage and fill factor increased with the increasing thickness of the mesoscopic ZSO layer, whereas the short-circuit current decreased with the increasing thickness except for the thinnest one. As a result, the perovskite solar cell having the 300-nm thick mesoscopic ZSO layer showed the highest conversion efficiency of 7.02%, which can be further improved by optimizing the fabrication process. In particular, the ZSO-based perovskite solar cell exhibited faster electron diffusion by 10 times and superior charge-collecting capability compared to the TiO₂-based solar cell with similar solar cell performance. Accordingly, ZSO is very promising as an alternative to the commonly used TiO₂.

What is claimed is:

1. A solar cell comprising:
(a) a transparent substrate;
(b) a first Zn₂SnO₄ layer formed on the transparent substrate;
(c) a second Zn₂SnO₄ layer formed on the first Zn₂SnO₄ layer;
(d) a CH₃NH₃PbI₃ layer formed on the second Zn₂SnO₄ layer; and
(e) a hole-transporting material layer formed on the CH₃NH₃PbI₃ layer.

2. The solar cell according to claim 1, wherein the first Zn₂SnO₄ layer has a porosity of 0-3%, and the second Zn₂SnO₄ layer has a porosity of 50-70% and an average pore size of 10-100 nm.

3. The solar cell according to claim 1, wherein the first Zn₂SnO₄ layer has a thickness of 100-120 nm.

4. The solar cell according to claim 1, wherein the second Zn₂SnO₄ layer has a thickness of 250-350 nm.

5. The solar cell according to claim 1, wherein the transparent substrate is selected from fluorine tin oxide (FTO), indium tin oxide (ITO), aluminum zinc oxide (AZO), niobium tin oxide (NTO) and zinc tin oxide (ZTO).
